(19) United States
(12) Patent Application Publication
(10) Pub. No.: US 2025/0142710 A1
(43) Pub. Date: May 1, 2025

(54) HEATSINK BUSBAR

(71) Applicant: Analog Devices, Inc., Wilmington, MA (US)

(72) Inventor: Hien Minh Pham, Wilmington, MA (US)

(21) Appl. No.: 18/497,354

(22) Filed: Oct. 30, 2023

(51) Int. Cl. H05K 1/02

(52) U.S. Cl. CPC H05K 1/0203; H05K 2201/066; H05K 2201/10272; H05K 2201/10522

(57) ABSTRACT

An electronic assembly is disclosed. The electronic assembly can include an assembly substrate of one or more electrical connections and an electronic device mounted to a first surface of the assembly substrate. The electronic device can include a plurality electronic modules mounted on and electrically connected to a first surface of a device substrate. The device substrate can have one or more traces. The electronic device can further include a busbar having a first portion extending along at least a portion of a lateral dimension of the substrate and a second portion having at least two fins extending non-parallel and away from the first portion and between the plurality of electronic modules to electrically and mechanically connect to the one or more traces disposed on the first surface of the substrate. The one or more fins can include a thermal conductive material.

### BACKGROUND

### Field of the Invention

The field relates to an electronic assembly and, in particular, to an electronic assembly including using a heatsink as a busbar.

### Description of the Related Art

Various electronic devices (e.g., high power regulators), in order to achieve higher power and output performance, experience conduction loss and generate significant amounts of heat. However, increasing the number of substrates to reduce the conduction lost increases the cost of the whole substrate and the presence of thermal resistance reduces transfer the heat to ambient air.

### SUMMARY

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these implementations are intended to be within the scope of the invention herein disclosed. These and other implementations will become readily apparent to those skilled in the art from the following detailed description of the preferred implementations having reference to the attached figures, the invention not being limited to any particular preferred implementations disclosed.

In one embodiment, an electronic assembly can comprise an assembly substrate comprising one or more electrical connection. The electronic assembly can comprise an electronic device mounted to a first surface of the assembly substrate. The electronic device can comprise a plurality of electronic modules mounted on and electrically connected to a first surface of a device substrate, the device substrate having one or more traces and a busbar. The busbar can comprise: a first portion extending along at least a portion of a lateral dimension of the device substrate; and a second portion having one or more projections extending non-parallel and away from the first portion and between the plurality of electronic modules to electrically and mechanically connect to the one or more traces disposed on the first surface of the device substrate, the one or more projections comprising a thermally conductive material.

In some embodiments, the one or more projections can comprise at least two projections. In some embodiments, the electronic assembly can include a second electronic device mounted on and electrically connected to a second surface of the assembly substrate opposite from the first surface. In some embodiments, the second electronic device comprises a processor. In some embodiments, the first portion extends to at least partially cover the plurality of electronic modules. In some embodiments, the electronic device and the second electronic device are electrically connected are connected to each other by the one or more electrical connections. In some embodiments, the one or more electrical connections comprise at least one of traces and vias. In some embodiments, the one or more projections are located above the plurality of electronic modules. In some embodiments, the one or more projections are soldered to the one or more traces. In some embodiments, the first portion comprises a planar surface. In some embodiments, the busbar comprises a top surface, which top surface is substantially flat. In some embodiments, the top surface comprises a layer of insulation, the insulation electrically isolating the top surface. In some embodiments, the top surface is attached to the top of the one or more projections with an adhesive. In some embodiments, the adhesive comprises a non-conductive glue. In some embodiments, the second portion comprises a lead frame. In some embodiments, a top surface is soldered to the lead frame. In some embodiments, the lead frame comprises one or more tie-bars connecting the projections of the lead frame. In some embodiments, the one or more tie-bars are bent in a profile based on a ratio of a gap between adjacent projections and a height of the projections. In some embodiments, the electronic assembly can include multiple lead frames to provide for multiple channels. In some embodiments, the one or more projections comprise a projection insulating layer near the substrate. In some embodiments, the projection insulating layer reduces potential solder wicking. In some embodiments, a number of projections corresponds to a number of traces disposed on the substrate. In some embodiments, the one or more projections can comprise at least one of a thin blade or a thick pillar. In some embodiments, the busbar comprises two or more sections, the two or more sections connecting to respective current paths (e.g., respective high current paths per package). In some embodiments, the electronic assembly can include a metal clip soldered to the busbar, wherein the metal clip is connected to a power source and thereby provides power to the electronic assembly. In some embodiments, the metal clip is connected to a power source and provides power to the electronic assembly. In some embodiments, the plurality of electronic modules comprise integrated circuitry field-effect transistors. In some embodiments, the plurality of electronic modules are soldered to the substrate. In some embodiments, the one or more projections comprise an aspect ratio of at least 2:1. In some embodiments, the first portion of the busbar comprises a heat sink portion configured to draw heat from (i) the device substrate and (ii) a top side of the plurality of electronic modules. In some embodiments, the busbar reduces a current path resistance. In some embodiments, the electronic assembly can include a first terminal and a second terminal connected to the one or more traces. In some embodiments, during operation, a first voltage is supplied to a first terminal. In some embodiments, during operation of the electronic assembly, a second voltage is supplying power from the second terminal. In some embodiments, the plurality of electronic modules comprise a package and a passive component connected to the package, wherein the package comprises a molding compound. In some embodiments, the package comprises a molding compound. In some embodiments, the component comprises a passive device. In some embodiments, the passive device comprises at least one of an inductor and transformer. In some embodiments, the busbar comprises a conductive material that is conductive to heat and electricity. In some embodiments, the busbar comprises a metal (e.g., copper or aluminum in various embodiments).

In another embodiment, an electronic package can include: a substrate comprising one or more traces disposed on a surface of the substrate and a voltage input and a voltage output connected to the one or more traces; a plurality of electronic modules configured to be mounted on and electrically connected to the substrate, wherein the one or more traces are disposed between modules of the plurality of electronic module; and a busbar extending along at least a portion of a length of the substrate, the busbar comprising one or more projections electrically and mechanically connected to the one or more traces.

In some embodiments, the one or more projections are soldered to the one or more traces. In some embodiments, the busbar comprises a top surface, which top surface is substantially flat. In some embodiments, the top surface comprises a layer of insulation, the insulation electrically isolating the top surface. In some embodiments, the top surface is attached to a top side of the one or more projections with an adhesive. In some embodiments, the adhesive comprises glue. In some embodiments, the busbar comprises a lead frame. In some embodiments, the top surface is soldered to the lead frame. In some embodiments, the lead frame comprises one or more tie-bars connecting the one or more projections of the lead frame. In some embodiments, the one or more tie-bars are bent in a profile based on a ratio of a gap between adjacent projections and a height of the projections. In some embodiments, the electronic package can include multiple lead frames to provide for multiple channels. In some embodiments, the one or more projections comprise a projection insulating layer near the substrate. In some embodiments, the projection insulating layer near the substrate reduces potential solder wicking. In some embodiments, a number of projections corresponds to a number of traces disposed on the substrate. In some embodiments, the one or more projections can comprise at least one of a thin blade, a thick pillar, or a custom shape. In some embodiments, the busbar comprises two or more sections, the two or more sections connecting to multiple high current paths per package. In some embodiments, the electronic package can comprise a metal clip soldered to the busbar for lateral power delivery. In some embodiments, the metal clip is connected to a power source and provides power to the electronic package. In some embodiments, the plurality of electronic modules comprise integrated circuitry. In some embodiments, the plurality of electronic modules are soldered to the substrate. In some embodiments, the one or more projections comprise an aspect ratio of 2:1. In some embodiments, the busbar comprises a heat sink portion configured to draw heat from the substrate and a top side of the plurality of electronic modules. In some embodiments, the busbar comprises a conductive material that is conductive to heat and electricity. In some embodiments, the busbar comprises a metal.

In another embodiment, a method of manufacturing an electronic assembly can include: providing a substrate comprising one or more traces and a voltage input and a voltage output connected to the one or more traces; mounting an electronic device package comprising a plurality of electronic modules, so as to mechanically affix the electronic device package upon, and to electrically connect the electronic device package to, a first surface of the substrate, wherein the one or more traces are disposed between modules of the plurality of electronic modules; mounting a second electronic device package, so as to mechanically affix the second electronic device package upon, and to electrically connect the second electronic device package to, a second surface of the substrate opposite from the first surface; and mounting, to the substrate, a busbar extending along a length of the substrate, the busbar comprising one or more projections to electrically and mechanically connect to the one or more traces.

In some embodiments, the method can include mounting a top surface to the busbar. In some embodiments, the method can include insulating the top surface. In some embodiments, the method can include plating the top surface. In some embodiments, the method can include stamping the busbar to form the one or more projections and one or more tie bars on either side of one or more gaps from forming the one or more projections. In some embodiments, the method can include bending the one or more tie bars. In some embodiments, the method can include insulating the one or more projections to electrically isolate the one or more projections. In some embodiments, the method can include mounting a second busbar to the substrate.

### BRIEF DESCRIPTION OF THE DRAWINGS

Various implementations will be described hereinafter with reference to the accompanying drawings. These implementations are illustrated and described by example only and are not intended to limit the scope of the disclosure. In the drawings, similar elements have similar reference numerals.

FIG. 1 illustrates is a schematic side view of an electronic assembly.

FIG. 2 is a schematic perspective view of a first electronic device.

FIG. 3 is a schematic side view of the first electronic device of FIG. 2.

FIG. 4 is a schematic perspective partially exploded view of a partially assembled first electronic device before a busbar is mounted to the electronic device of FIGS. 2 and 3.

FIG. 5 is a schematic perspective view of the example first electronic device of FIGS. 2-4 after assembly.

FIG. 6 is a schematic front view of the first electronic device.

FIG. 7 is a schematic front view of the first electronic device having an insulation layer disposed over a top surface of the busbar.

FIGS. 8-9 are schematic perspective views of the first electronic device in which another implementation of the busbar comprises a lead frame.

FIGS. 10-13 illustrates various examples of the busbar, according to various implementations.

FIGS. 14-16 illustrate another example of the first electronic device in which busbars are used for an input current path and an output current path.

FIG. 17 illustrates a schematic perspective view of the first electronic device of FIG. 14-16 which further comprises a metal clip.

FIG. 18 illustrates the metal clip electrically and mechanically connected to the busbar for lateral power delivery.

FIG. 19 illustrates another implementations of the metal clip electrically and mechanically connected to the busbar for lateral power delivery.

FIGS. 20-21 illustrate various schematic perspective views of implementations of tie-bars of the lead frame.

FIG. 22 illustrates an example process of processing busbars, according to an implementation.

FIG. 23 is a schematic perspective view of a lead frame for low profile electrical modules.

FIG. 24 is a schematic perspective view of a lead frame for tall profile electrical modules.

FIG. 25 illustrates schematic perspective views of the busbar positioned over even number rows of electric modules.

FIG. 26 illustrates schematic perspective views of the busbar positioned over odd number rows of electric modules.

FIG. 27 illustrates another implementation of the first electronic device in which the busbar operates as a heatsink.

### DETAILED DESCRIPTION

The present disclosure may be understood by reference to the following detailed description. It is noted that, for purposes of illustrative clarity, certain elements in various drawings may not be drawn to scale, may be represented schematically or conceptually, or otherwise may not correspond exactly to certain physical configurations of embodiments.

Implementations related to busbars that can serve as a heatsink. The high current capability of a busbar and the heat exchanging performance of a heatsink can be combined to create a busbar that also acts as a heatsink. As the requirement of output current for voltage regulators increases significantly (e.g., to currents in a range of 800A-1000A), vertical power modules can be a new approach to power delivery. Current solutions place a voltage regulator on an opposite side of a substrate (e.g., PCB) under an integrated circuit (IC), such as an application-specific integrated circuit (ASIC), on the top side. As a result, the conduction loss due to ultra-high output current can be reduced due to the short connections between the vertical power module and ICs on the top side through a via-in-pad. The conduction loss can occur due to resistance of the various components through which the current passes, this lost current can generate heat in the assembly. However, the conduction loss due to input current is often overlooked. Electrical components can suffer excessive conduction loss due to excessive trace resistance on a substrate for input current path. Modification to the substrate can reduce power loss, in some cases by half, but this reduction is not enough. Another approach can include adding additional layers to the PCB to reduce the loss, but a trade-off is that the substrate cost can increase over 30%.

A heatsink busbar design can be similar to an extruded fin heatsink, except, unlike a traditional heatsink, the heatsink busbars disclosed herein can provide electrical connections as well as heat dissipation. A heatsink can have as many projections (e.g., fins, pillars, blades, etc.) as possible to increase surface area to optimize thermal performance. However, it can also depend on the number of contact points made by the fine to the substrate to reduce the current path resistance. For example, in finned heatsinks, fins can be inserted into the gaps between electrical modules. Thus, the size of the fin gap can depend on the module size. The busbar can be placed such that the fins can form a solder connection with exposed buses and/or traces on the substrate and be positioned on top of the electrical modules with an adhesive filling an air gap. The direct connection between the busbar and the substrate can allow the effective resistance of the high current path to drop, reducing the conduction loss and excessive substrate heating. In addition, the busbar can act as a heatsink as well to draw the heat from the substrate and the top side of the electrical modules to a surface exposed to an ambient environment.

Other implementations of the busbar can include a lead frame to form the blades which functions like the fins of the heatsink busbar. Tie-bars between the blades of the lead frame can hold the blades together vertically and assure its coplanarity. To further reduce the effective resistance of the lead frame, a solid and/or planar piece of metal can be soldered down on top of the lead frame. The flat piece can be adhered to the lead frame to provide electrical isolation as the glue acts as a thermal interface and insulation.

Having multiple electrical modules with slightly different heights can present a challenge for picking and placing during testing and assembly of the vertical power module as a vacuum seal applied to the module may not be strong enough. Thus, the heatsink busbar can include a planar top surface to assist in improving the vacuum seal. The heatsink busbar can also be used for multiple high current paths in a vertical power module. The flat top surface, if uninsulated, can be connected to another bus in another system by soldering down a metal clip. The metal clip can extend to the locations on the PCB to reduce high current path conduction loss in the system. The metal clip extension piece can also act as a heatsink as well.

The heatsink busbar can also be used in lateral power system as well. If both an input current path and an output current path are optimized by the busbar, the conduction loss due to lateral power delivery can be reduced. If the IC package has the power path brought up through the top side, a metal clip can be soldered between the IC and power module.

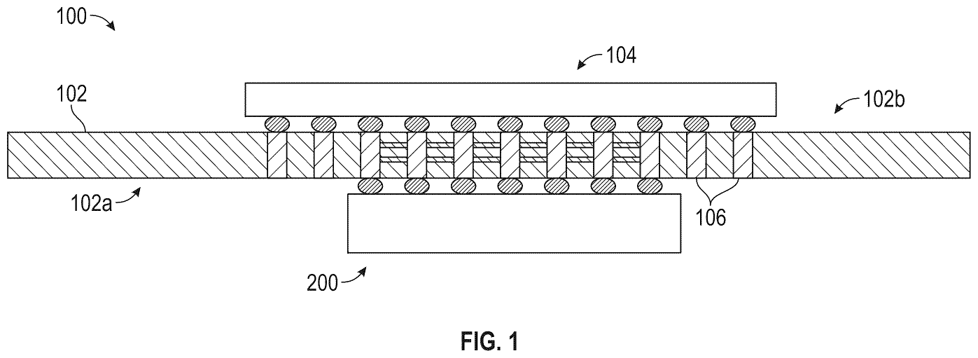

FIG. 1 illustrates an example electronic assembly 100 including an assembly substrate 102, a first electronic device package 200 (also referred to herein as a first electronic device) mounted to a first side 102a of the assembly substrate 102, and a second electronic device package 104 (also referred to herein as a second electronic device) mounted to a second side 102b opposite the first side 102a of the assembly substrate 102. The electronic device 200 and second electronic device package 104 can be attached to the assembly substrate 102 using a conductive adhesive, such as solder, a conductive epoxy, etc. The assembly substrate 102 can include one or more electrical connections 106 (e.g., traces and/or vias). In some implementations, the electronic device 200 and the second electronic device 104 can be electrically connected to each other by the one or more electrical connections 106. In some implementations, the second electronic device package 104 can include a processor, such as an application-specific integrated circuit, a graphics processing unit (GPU), a central processing unit (CPU), or any high power devices that utilize a low input voltage and that, as a result, need a high input current.

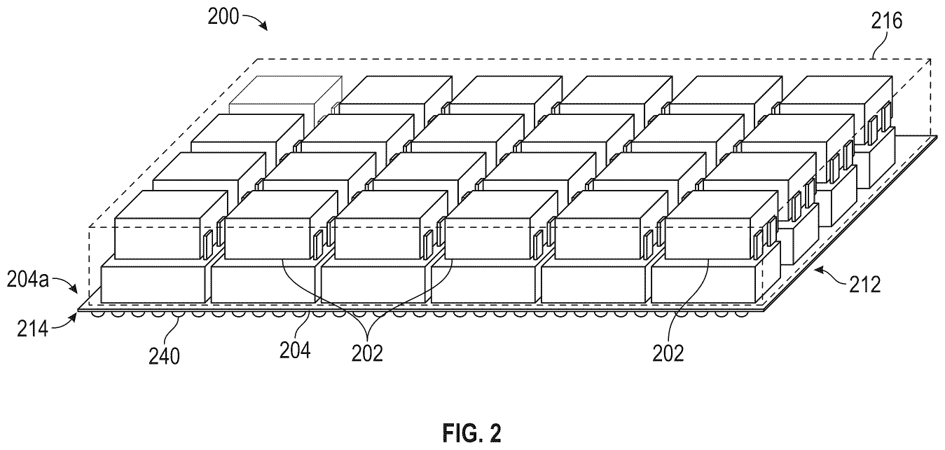

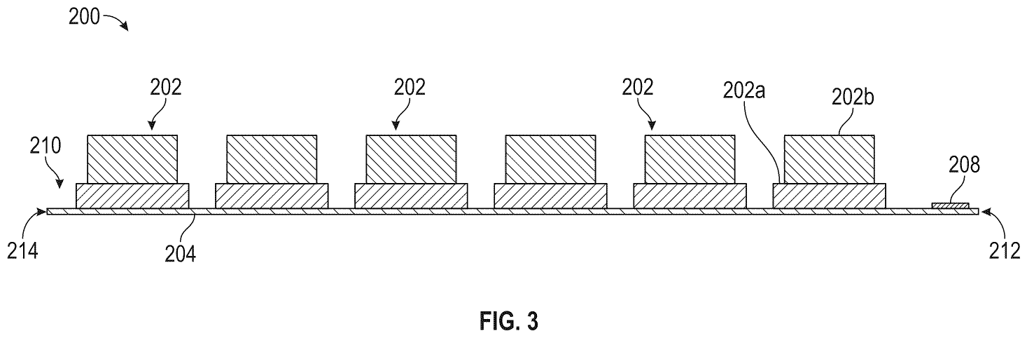

FIGS. 2 and 3 illustrate an example electronic device 200. FIG. 2 is a schematic perspective view of the example electronic device 200. FIG. 3 is a schematic side view of the electronic device 200. The electronic device 200 can include a plurality electronic modules 202 mounted on and electrically connected to a device substrate 204 on a first surface 204a of the device substrate 204. The electronic modules 202 can be attached to the device substrate 204 using a conductive adhesive, such as solder, a conductive epoxy, etc. The electronic modules 202 can include a package 202a and a component 202b connected to a top surface of the package 202a. The package 202a can comprise any suitable type of electronic component, such as integrated device die(s), other types of active components, passive components (e.g., resistors, capacitors, inductors, integrated circuits, field-effect transistors (FETs), transformers, etc.), sensors, microelectromechanical systems (MEMs) components, or any other suitable type of component embedded in an encapsulant. In some implementations, the electronic modules 202. The component 202b can comprise any suitable type of electronic component, such as integrated device die(s), other types of active components, passive components (e.g., resistors, capacitors, inductors, integrated circuitry, field-effect transistors (FETs), transformers, etc.), sensors, microelectromechanical systems (MEMs) components, or any other suitable type of component. The electronic modules 202 can be and/or include a module similar or identical to those discussed in U.S. application Ser. No. 16/681,136, filed Nov. 12, 2019, titled “Electronic Module for High Power Applications,” now U.S. Pat. No. 11,410,977, and/or U.S. application Ser. No. 17/325,080, filed May 19, 2021, titled “Electronic Component,” the disclosure of which are hereby incorporated by reference in its entirety. In some implementations, the electronic modules 202 can include field-effect transistors (FETs).

In some implementations, the electronic modules 202 can be arrayed on the first surface 204a. In some implementations, the device substrate 204 can also include an electrical terminal(s) 240 formed on a second surface 204b of the device substrate 204. In some implementations, the electrical terminal(s) 240 can be a molded ball grid array (BGA) package, a land grid array, and/or a vertical interconnect PCB connections. The device substrate 204 can be mounted assembly substrate 102 via the electrical terminal(s) 240.

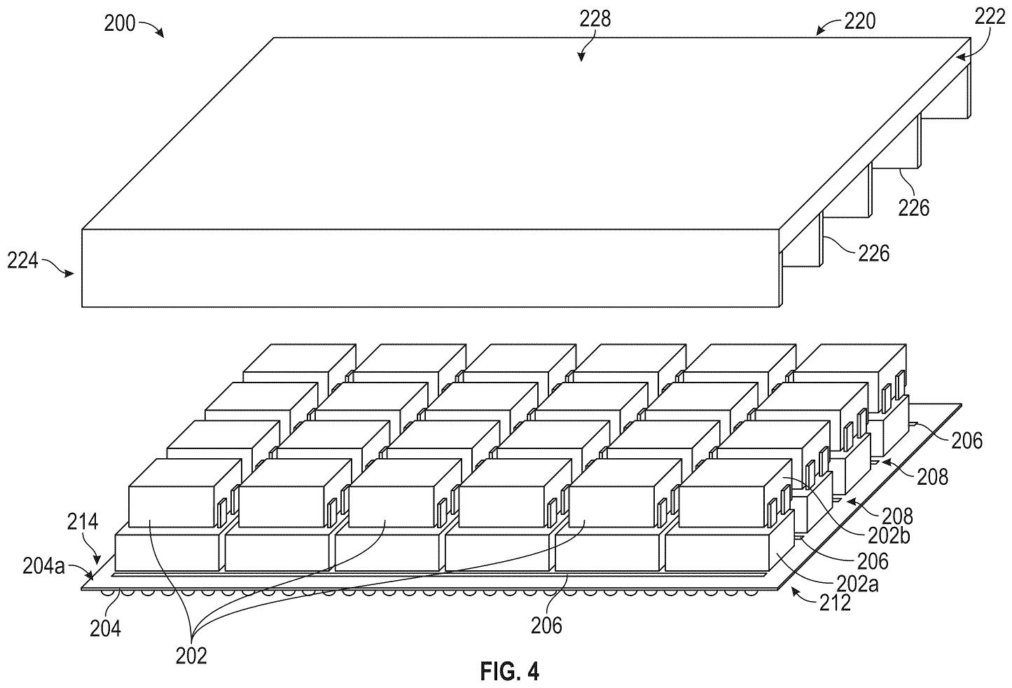

As shown in FIG. 4, the device substrate 204 can also have one or more laterally extending traces 206 that provide horizontal electrical communication within the electronic device 200. The one or more laterally extending traces 206 can be electrically connected to a first terminal 208 and a second terminal 210. The first terminal 208 can be positioned on a first edge 212 of the device substrate 204 and the second terminal 210 can be on a second edge 214 different from the first edge 212. During operation of the electronic assembly 100, a first voltage can be supplied to the first terminal 208. Additionally or alternative, during operation of the electronic assembly 100, a second voltage is supplying power from the second terminal 210 to another device. In some implementations, a molding and/or encapsulant compound 216 can be molded over at least portions of the electronic modules 202 (e.g., molded over the first surface 204a of the electronic device 200 to protect the electronic modules 202).

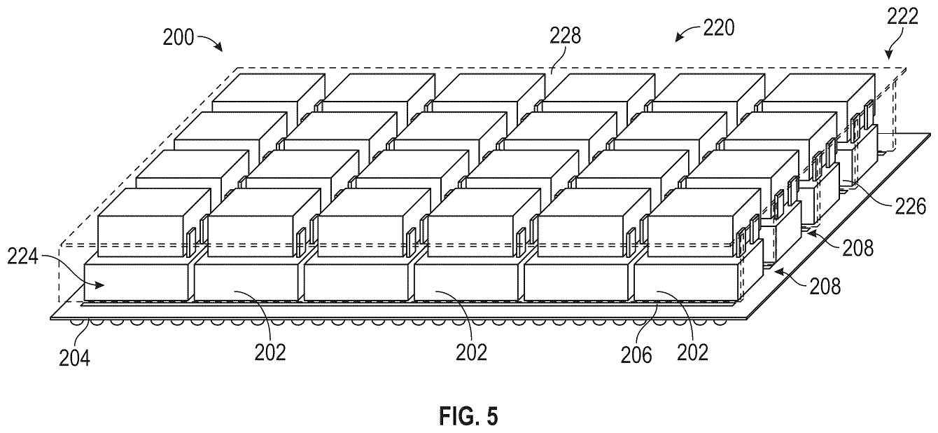

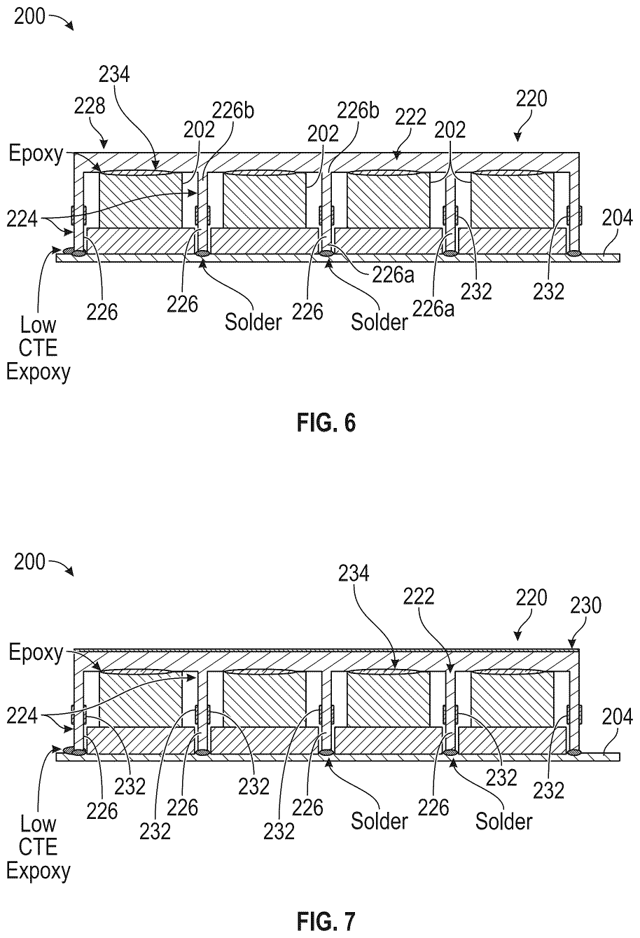

The electronic device 200 can further include a heatsink busbar 220 as shown FIGS. 4-7. FIG. 4 is a schematic perspective view of the example electronic device 200 before assembly. FIG. 5 is a schematic perspective view of the example electronic device 200 after assembly. FIG. 6 is a schematic side view of the electronic device 200. FIG. 7 is a schematic side view of the electronic device 200 having an insulation later 230 disposed over a top surface of the busbar 220. The heatsink busbar 220 can include a first portion 222 extending along at least a portion of a lateral dimension of the device substrate 204 and a second portion 224 having at least two projections (e.g., fins 226) extending non-parallel and away from the first portion 222. Although the illustrated embodiments include projections comprising fins 226, in some embodiments, the projections can comprise pillars, blades, or other projecting pieces. The heatsink busbar 220 can be positioned above the electronic modules 202 such that the heatsink busbar 220 can rest on a top surface of the electronic modules 202 in some implementations. A glue and/or an epoxy can fill in a gap between the top surface of the electronic modules 202 and the heatsink busbar 220. In some implementations, a thermally conductive material (e.g., thermal interface material) can be provided between the first portion 222 and the modules 202. In some implementations, the first portion 222 of the heatsink busbar 220 can include a heat sink portion to draw heat from the device substrate 204 and a top side of the electronic modules 202 to the heat sink portion during operation of the of the electronic assembly to dissipate heat into the ambient environment. The number of fins 226 can be based on at least a number of traces 206. The fins 226 can shaped to be at least one of a thin blade, a thick pillar, or a custom shape. The heatsink busbar 220 can use multiple shapes besides the thin blade and/or fin shape for contacts with the device substrate 204. In some implementations, as described below, the thin blade and/or fin 226 can be used for high aspect ratio application and to reduce their footprint. The heatsink busbar 220 can be of one solid piece such that the first portion 222 and second portion 224 are a unified structure.

The fins 226 can extend between the electronic modules 202, and a first end 226a of the fins 226 can electrically and mechanically connect to the traces 206 disposed on the first surface 204a. In some implementations, the fins 226 can be attached to the traces 206 using a conductive adhesive, such as solder, a conductive epoxy, etc. The heatsink busbar 220 can be attached to the traces 206 such that the fins 226 can form a connection with the traces 206 on the device substrate 204. The direct connection between the busbar 220 and the traces 206 of the device substrate 204 can allow the effective resistance of the high current path along the traces 206 to drop significantly, reducing the conduction loss and excessive substrate heating to a very minimal amount. Busbars are conductive structures having low resistance and high current-carrying capacity. By integrating the busbar 220 directly with the traces 206, the combination can improve power distribution and grounding, leading to improved electrical performance and heat dissipation. The busbar 220 can be connected to the traces 206 at specific points, forming a robust and efficient conductive network. These connection points facilitate low-resistance pathways for power and ground signals.

The heatsink busbar 220 can also enable low-loss power distribution, minimizing voltage drops and ensuring consistent power delivery to the electronic modules 202 on the device substrate 204, which can result in improved performance and/or reduced susceptibility to signal interference. The traces 206 can provide power and ground connection to input and output terminals of the electronic modules 202. The electronic modules 202 at the front of the electronic device 200 can receive 100% of the load current. As the load current continues along the traces 206 and through the subsequent electronic modules 202, the current steps down. The electronic modules 202 can regulate the power incoming along the traces 206, which can result in power loss. The electronic modules 202 can perform as a voltage regulator to maintains a steady output voltage regardless of variations in input voltage, load current, or temperature. Voltage regulators can be used to ensure that sensitive electronic components receive a stable and consistent supply of power. During operation, the voltage regulator adjusts the input voltage to provide a constant output voltage. This adjustment process involves dissipating excess energy as heat. The amount of heat generated can be proportional to the voltage drop between the input and output, multiplied by the current flowing through the regulator. The regulator's internal resistance can contribute to the voltage drop and, consequently, the heat generated. The amount of heat generated by the electronic modules 202 can be significant depending on factors such as the voltage difference between the input and output, the current being regulated, and/or the efficiency of the voltage regulator itself. Therefore, heat dissipation mechanisms, such as heat sinks or thermal pads, can be employed to ensure that the temperature of the voltage regulator remains within safe operating limits.

An epoxy having a low coefficient of thermal expansion (CTE) can also be used to attach the fins 226 to the device substrate 204. In some implementations, the fins 226 can include a fin insulating layer 232 located near the first surface 204a to reduce potential solder wicking. In some implementations, the heatsink busbar 220 reduces a current path resistance. In addition to resistance reduction, the inductance of the high current path is also reduced significantly which is very important in high current application.

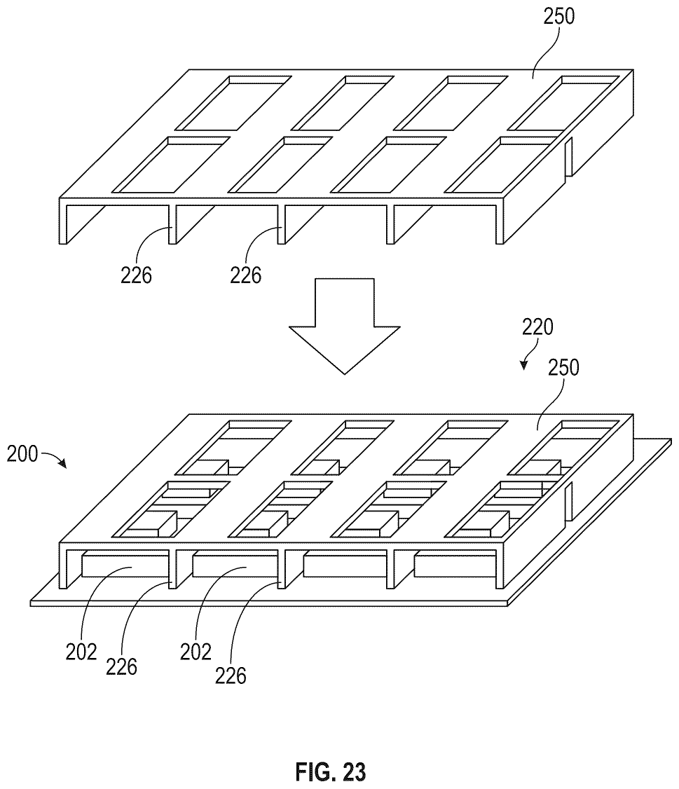

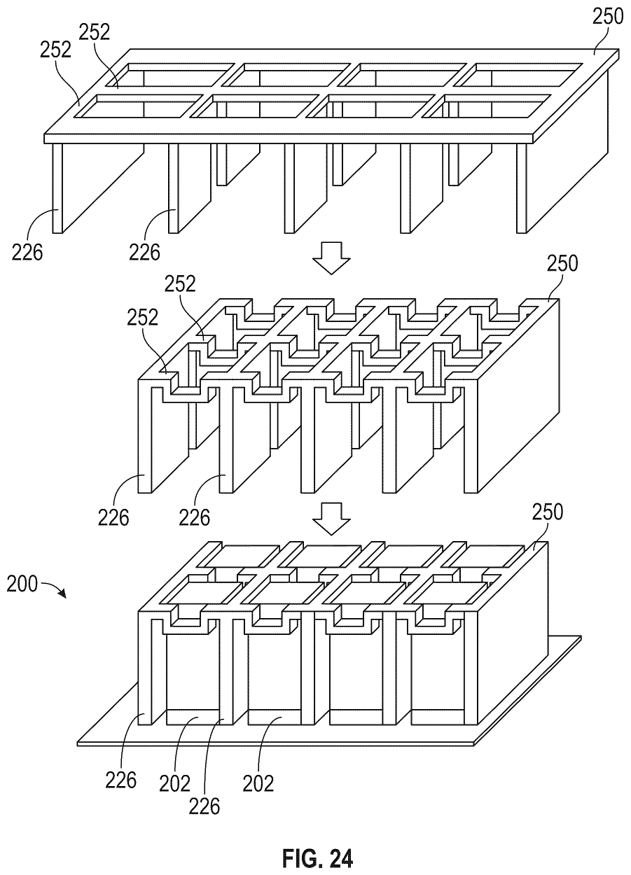

The fins 226 can have an aspect ratio defined by the ratio of a height or length L of the fins 226 to a width W or diameter of the fins 226. The aspect ratio can be greater than 1:1, e.g., at least 2:1, for example, in a range of 1:1 to 10:1, in a range of 1:1 to 5:1, in a range of 1:1 to 3:1, in a range of 2:1 to 7:1, or in a range of 2:1 to 5:1. In some implementations, the aspect ratio can be less than 1:1, for example, in a range of 0.2:1 to 1:1. In various implementations, the width of the fins 226 can be in a range of 0.05 mm to 8 mm, in a range of 0.075 mm to 7 mm, in a range of 0.095 mm to 5 mm, or in a range of 0.1 mm to 3 mm. FIGS. 23 and 24 illustrate example lead frame designs of the electronic device 200 for different aspect ratios, according to various implementations. FIG. 23 is a schematic perspective view of a heatsink busbar 220 for low profile electronic modules 202. In contrast, FIG. 24 illustrates a heatsink busbar 220 positioned over electronic modules 202 having a tall profile. In some implementations, the tie-bars 252 can be bent as shown in FIG. 24.

The fins 226 extend above the electronic modules 202. A gap 234 between the electronic modules 202 and the first portion 222 can be filled with an adhesive, such as glue, which can be thermally conductive so as to enhance heat transfer to the first portion 222. The heatsink busbar 220 can comprise a thermal and/or electrically conductive material that is highly conductive to heat and electricity (e.g., copper, gold, silver, etc.). The first portion 222 can include a top surface 228. In some implementations, the top surface 228 can be a planar surface for placement using surface mount technology (SMT). In some implementations, the top surface 228 can include a layer of insulation 230 (see FIG. 7) that electrically isolates the top surface 228.

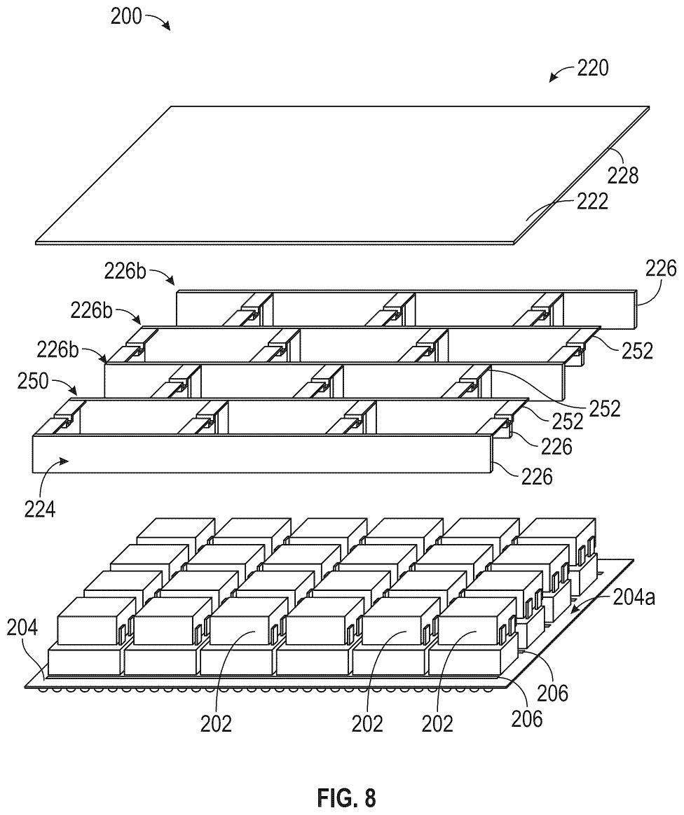

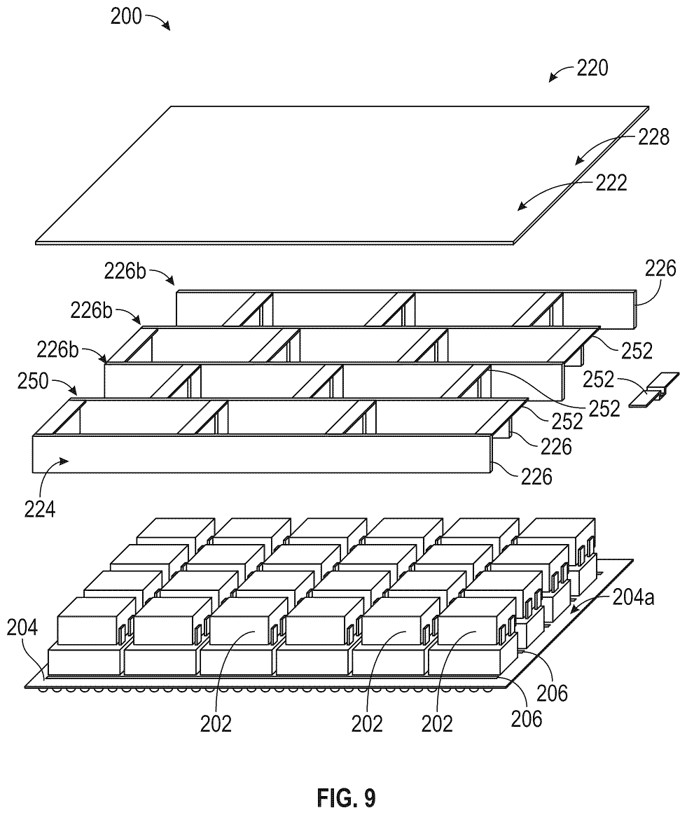

FIGS. 8-9 illustrates a schematic perspective view of the electronic device 200 in which another implementation of the heatsink busbar 220 can include a lead frame 250. A lead frame can comprise a thin sheet of metal (e.g., copper) that can be bent, stamped, and/or otherwise shaped into a desired shape or configuration. The lead frame 250 can provide electrical communication to the traces 206 and a thermal pathway to convey heat away from the electronic modules 202. The lead frame 250 can form the second portion 224. In such an implementation, the first portion 222 and the second portion 224 (e.g., lead frame 250) can be separate pieces that are attached together to form the heatsink busbar 220. For example, the first portion 222 can be attached to a second end 226b of the fins 226 of the second portion 224 using a conductive adhesive, such as solder, a conductive epoxy, etc. to further reduce the resistance and/or inductance of the heatsink busbar 220. In other implementations, the first portion 222 can be attached to the fins 226 using a non-conductive adhesive such as glue to electrically isolate top surface 228. In some implementations, the heatsink busbar 220 can include multiple lead frames 250 for multiple channels.

The lead frame 250 can include tie-bars 252 extending between each of the fins 226. The tie-bars 252 can be bent to allow the fins 226 to have the same height in case the height and width of the electronic modules 202 are not the same. The number of tie-bars 252 can be increased to better secure the lead frame 250. In some implementations, the lead frame 250 can be connected to the device substrate 204 prior to the electronic modules 202 being connected to the device substrate 204. If using an open-frame design, the lead frame 250 can be further secured to the device substrate 204 using a non-conductive adhesive such as an epoxy.

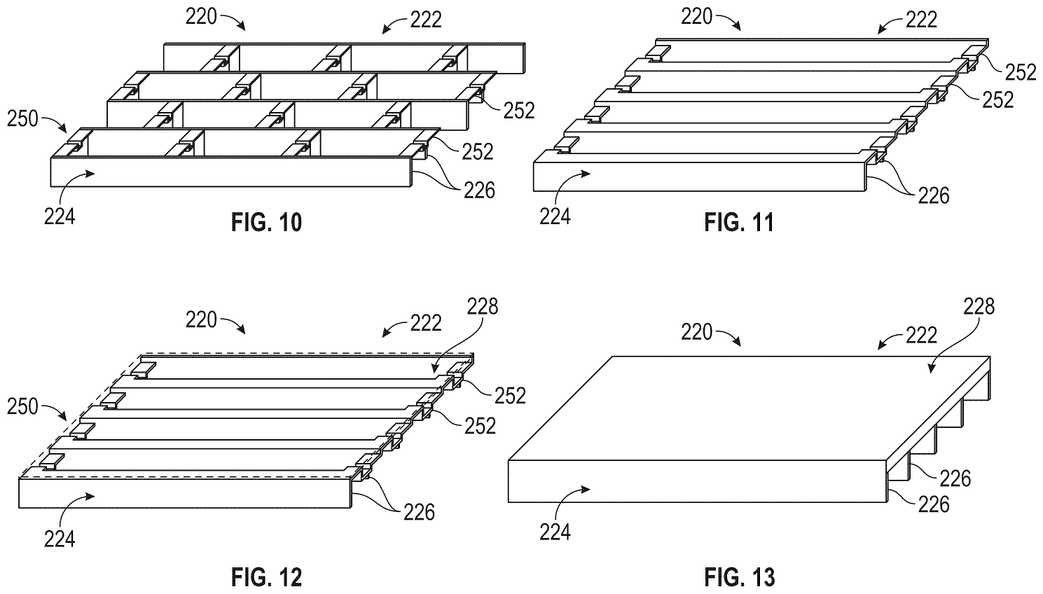

FIGS. 10-13 illustrates various examples of heatsink busbar 220 according to various implementations. For example, FIG. 10 illustrates a lead frame 250 without a first portion 222 that can form one implementation the heatsink busbar 220. In another implementation, as shown in FIG. 11, another implementation of the lead frame 250 without a first portion 222 can form another implementation the heatsink busbar 220. As seen in another implementations as depicted in FIG. 12, the lead frame 250 of FIG. 11 can include a first portion 222 having a top surface 228. Lastly, FIG. 13 depicts a solid heatsink busbar 220 (as shown in FIGS. 4-7) having a first portion 222 and a second portion 224.

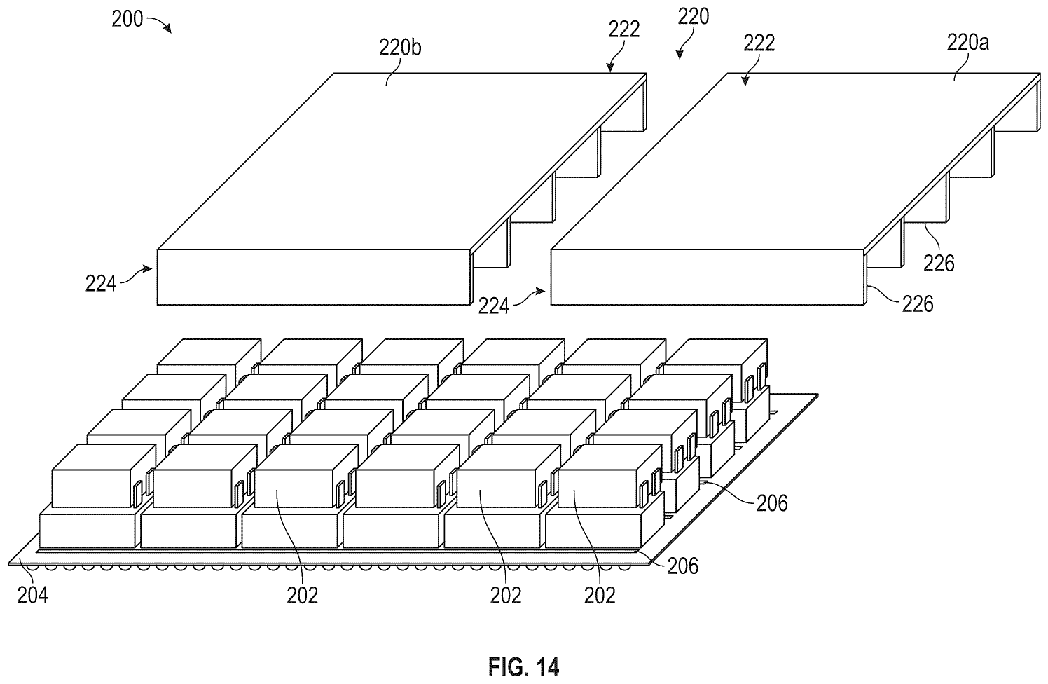

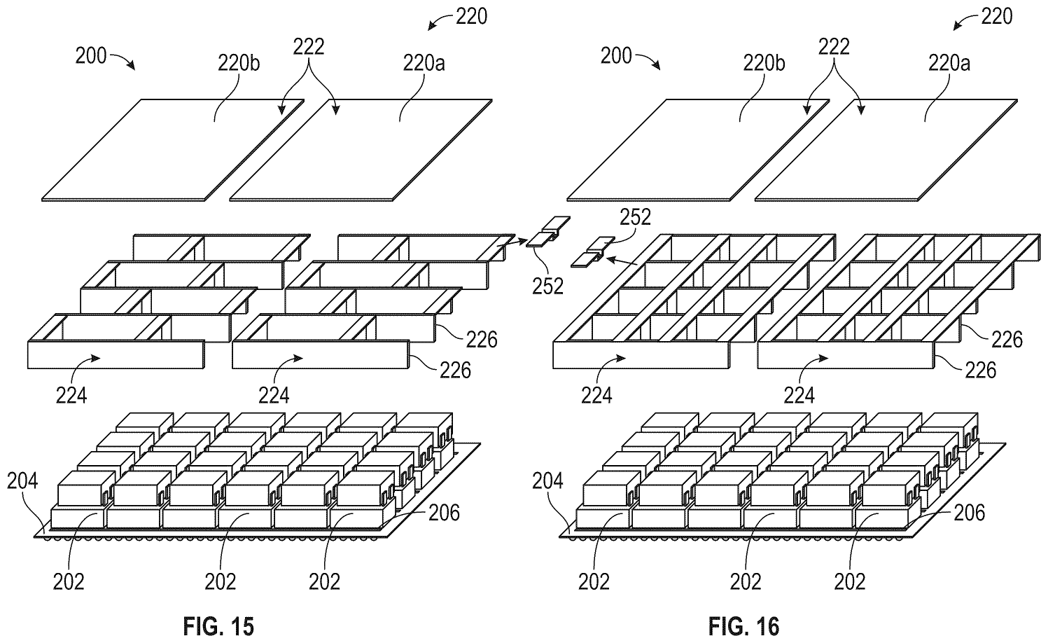

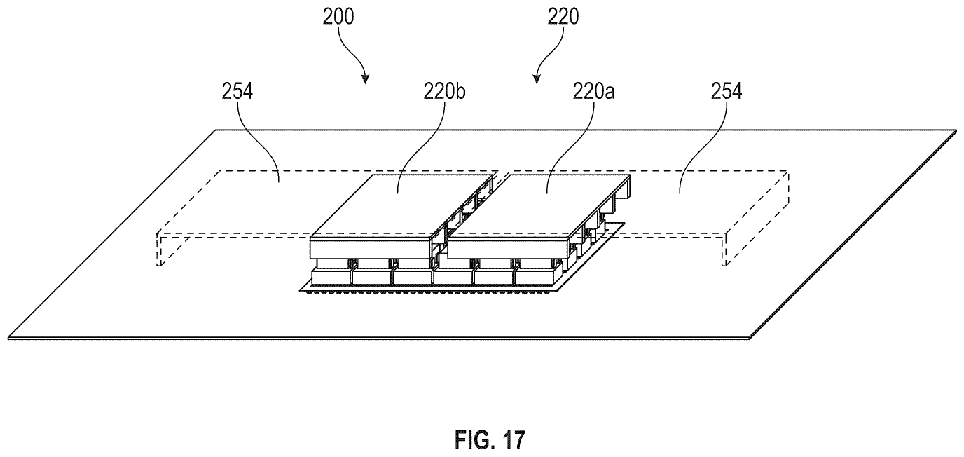

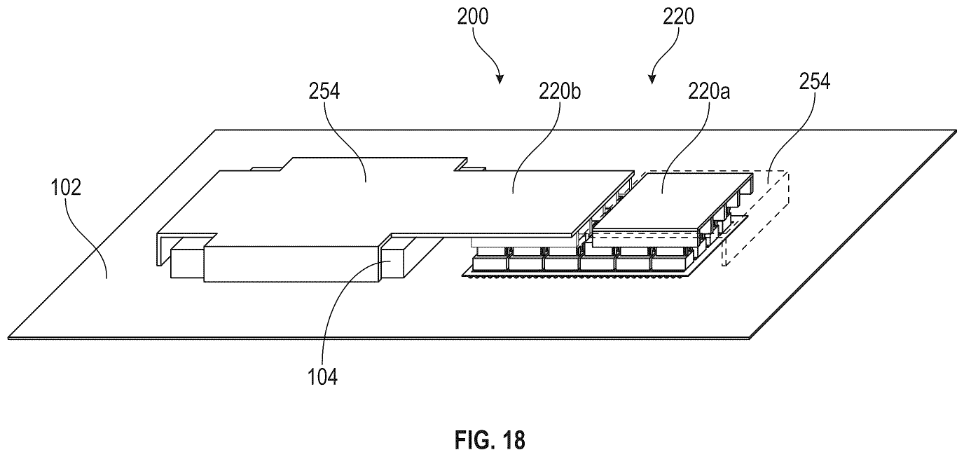

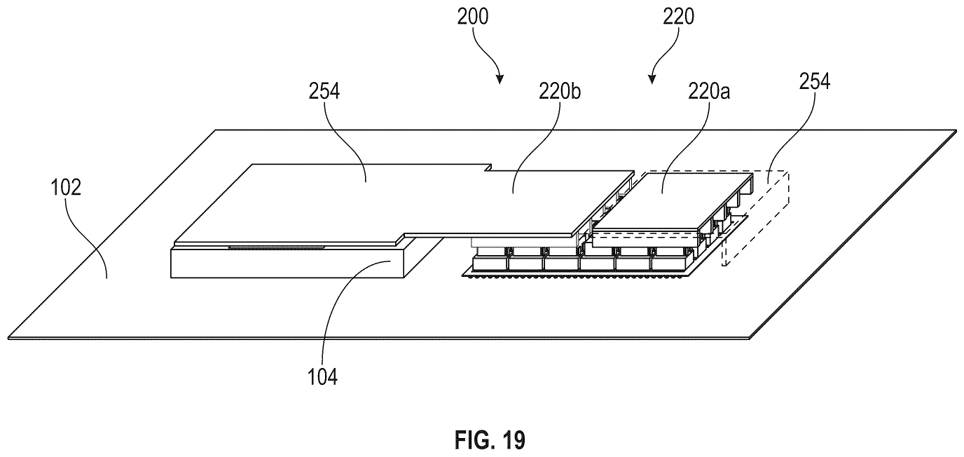

FIGS. 14-16 illustrate another example of the electronic device 200 in which a busbars 220 can be used for an input current path and an output current path. In some implementations, the heatsink busbar 220 can include two or more sections. The two or more sections can connect to multiple high current paths per part. For example, a busbar 220a can be used for a voltage in high current path and a busbar 220b can be used for a voltage out high current path. FIG. 17 illustrates a schematic perspective view of the electronic device 200 of FIG. 14-16 which further includes a metal clip 254. If a voltage loss through assembly substrate 102 and/or device substrate 204 is too high, the metal clip 254 can be mechanically and/or electrically attached with a conductive adhesive (e.g., solder, a conductive epoxy, etc.) to the heatsink busbar 220 (e.g., busbar 220a and busbar 220b). In another implementation, as shown in FIG. 18, the metal clip 254 can be electrically and mechanically connected to the heatsink busbar 220 for lateral power delivery if the second electronic device package 104 is attached to the same side of the assembly substrate 102 as the electronic device 200. For example, if both an input current path and an output current path are optimized by the heatsink busbar 220, the conduction loss due to lateral power delivery can be reduced. Additionally or alternatively, as shown in FIG. 19, if the second electronic device package 104 has a power path on a top side of the second electronic device package 104, a conductive material can be attached between the electronic device 200 and second electronic device package 104. Thus, there can be direct power delivery from the electronic device 200 to the second electronic device package 104 using metal clip 254. In some implementations, the metal clip 254 is connected to a power source (not shown) and provides power to the electronic assembly 100.

In the embodiments disclosed herein, the heatsink busbar 220 can comprise any suitable type of conductive material, such as a metal. In some embodiments, the heatsink busbar 220 can comprise copper. In some embodiments, the heatsink busbar 220 can comprise aluminum which can be plated with a solderable material. For example, in the embodiments of FIGS. 17-19, the top surface can comprise copper or aluminum plated with a solderable material to facilitate soldering.

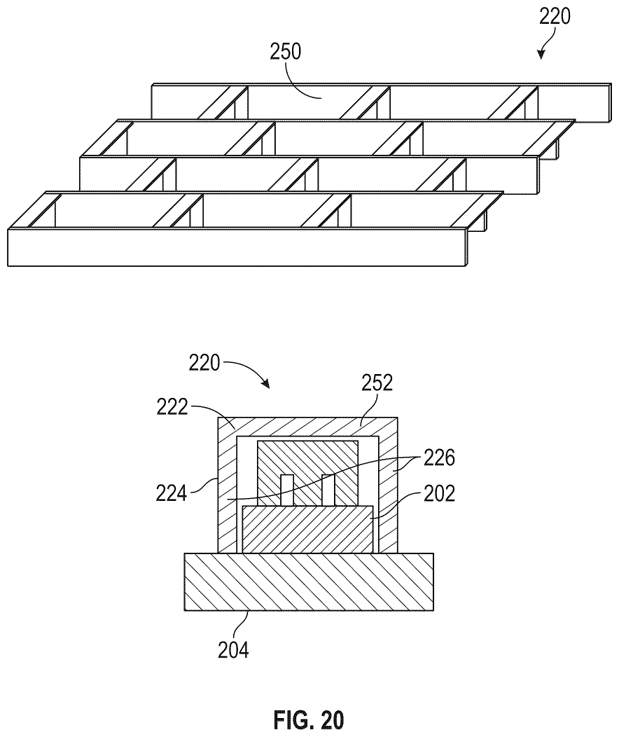

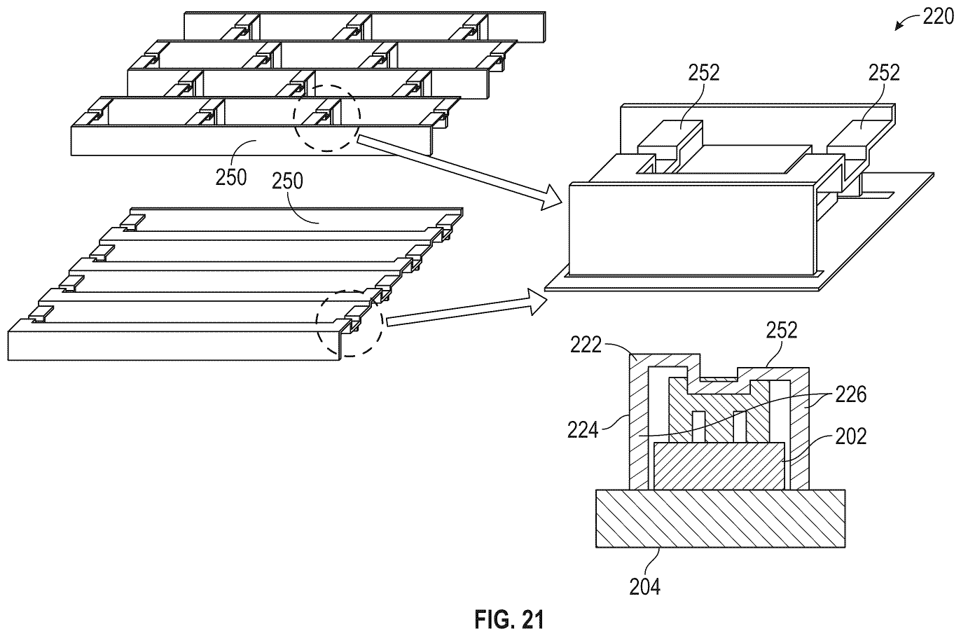

FIGS. 20-21 illustrate various implementations of the tie-bars 252. In FIG. 20, the tie-bars 252 can be a straight tie-bar such that there are no bends in the tie-bars between the fins 226. In FIG. 21, the tie-bars 252 can be bent tie-bars to accommodate different aspect rations between the fins 226 and to assist with coplanarity. As mentioned above, the tie-bars 252 can be bent to allow the fins 226 to have the same height in case the height and width of the electronic modules 202 are not the same. In various embodiments, the tie-bars 252 can be bent in a profile based on a ratio of a gap between adjacent projections (e.g., fins 226) and a height of the projections (e.g., fins 226).

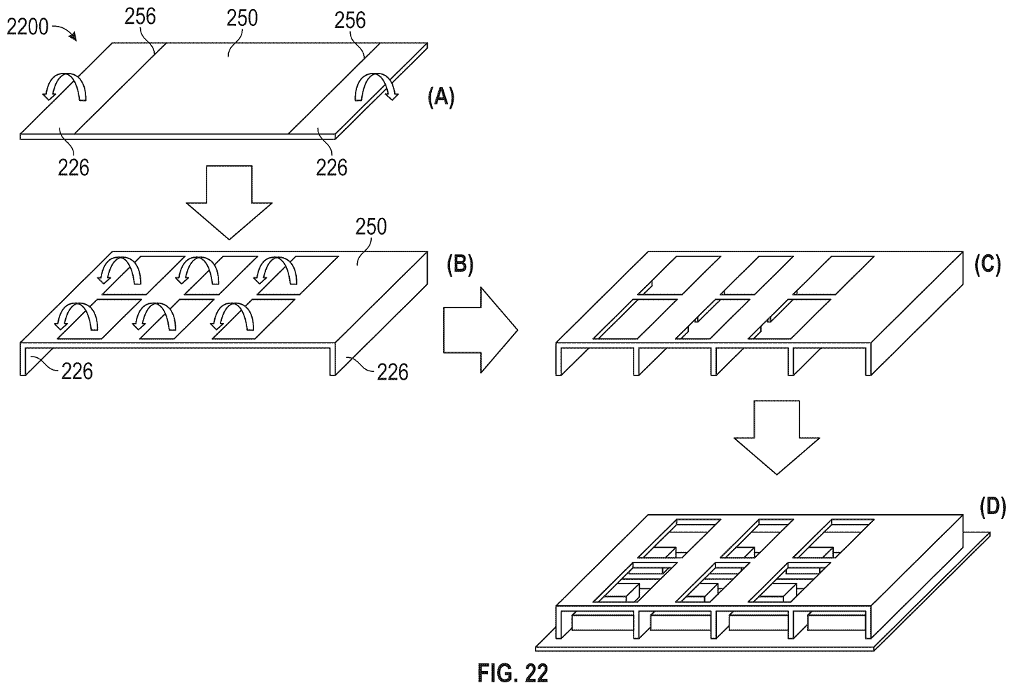

FIG. 22 illustrates an example process 2200 of processing busbars, according to an implementation. At (A), a lead frame 250 can be manipulated (e.g., bent) along one or more edges 256 to form a first set of fins 226. At (B), the lead frame 250 can be further manipulated (e.g., stamped, cut, and/or bent) to form one or more interior fins 226. The fins 226 of Steps (A) and (B) can be of similar heights or different heights depending on the dimensions of the electronic modules 202 surrounded by the fins 226. The fins 226 of Step (A) and (B) can be formed from stamping the heatsink busbar 220. Tie-bars 252 can also bent based at least on the height of the electronic modules 202 and/or other factors. At (C), the lead frame 250 can be electrically and mechanically attached to a device substrate 204 to form the electronic device 200 shown in Step (D).

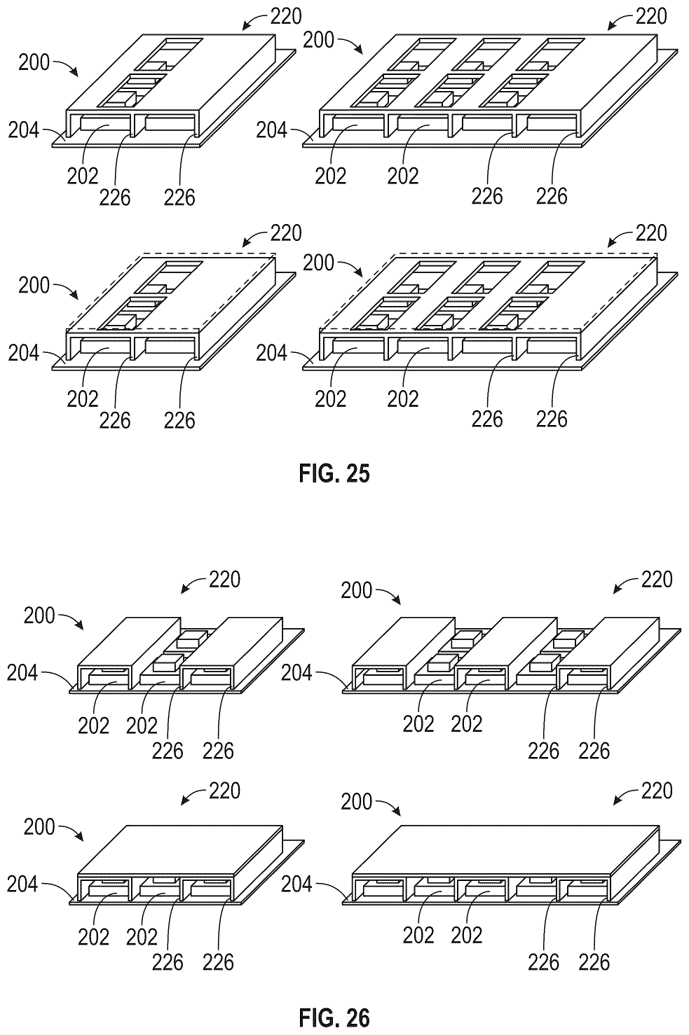

FIGS. 25 and 26 illustrate example implementations of the lead frame 250 of the electronic device 200 according to various implementations. FIG. 25 illustrates schematic perspective views of the busbar positioned over even number rows of electric modules 202. FIG. 26 illustrates schematic perspective views of the busbar positioned over odd number rows of electronic modules 202. The lead frame 250 can be positioned over even numbered columns (as shown in FIG. 25) or odd number columns (as shown in FIG. 26) of the electronic modules 202. In the illustrated embodiment of FIG. 26, the busbar 220 can be formed of a simpler construction as compared to the busbar 220 of FIG. 25. However, the busbar 220 of FIG. 26 may be used primarily for devices with odd number rows of electronic modules 202, whereas the busbar 220 of FIG. 25 can be used for devices with even or odd numbered rows of electronic modules 202.

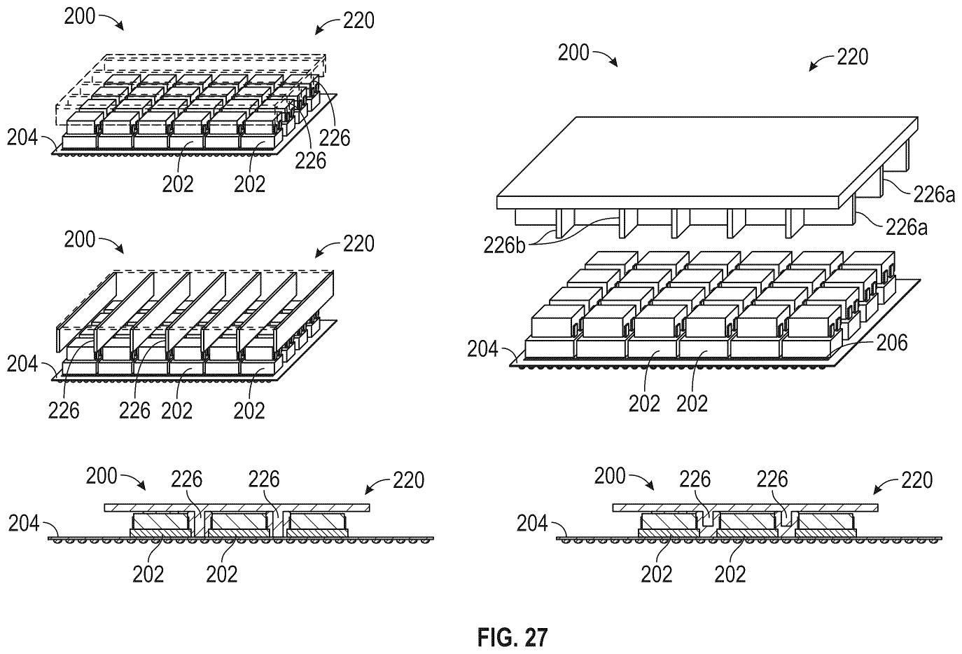

FIG. 27 illustrates another implementation of the electronic device 200 which can operate as a heatsink. The electronic device 200 can include fins 226 of a heatsink busbar 220 which can be arranged to align parallel with the traces 206 and/or perpendicular to the traces 206. Additionally or alternatively, the fins 226 can be in a cross-configuration in which the fins 226 comprise both fins 226a parallel to the traces 206 and fins 226b that are perpendicular to the traces 206. An adhesive (e.g., epoxy) can then be used to fill in any gaps between the electronic modules 202 and the heatsink busbar 220.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

Several illustrative examples of heatsink busbars and related systems and methods have been disclosed. Although this disclosure has been described in terms of certain illustrative examples and uses, other examples and other uses, including examples and uses which do not provide all of the features and advantages set forth herein, are also within the scope of this disclosure. Components, elements, features, acts, or steps may be arranged or performed differently than described and components, elements, features, acts, or steps may be combined, merged, added, or left out in various examples. All possible combinations and subcombinations of elements and components described herein are intended to be included in this disclosure. No single feature or group of features is necessary or indispensable.

Certain features that are described in this disclosure in the context of separate implementations may also be implemented in combination in a single implementation. Conversely, various features that are described in the context of a single implementation also may be implemented in multiple implementations separately or in any suitable subcombination. Moreover, although features may be described above as acting in certain combinations, one or more features from a claimed combination may in some cases be excised from the combination, and the combination may be claimed as a subcombination or variation of a subcombination.

Further, while illustrative examples have been described, any examples having equivalent elements, modifications, omissions, and/or combinations are also within the scope of this disclosure. Moreover, although certain aspects, advantages, and novel features are described herein, not necessarily all such advantages may be achieved in accordance with any particular example. For example, some examples within the scope of this disclosure achieve one advantage, or a group of advantages, as taught herein without necessarily achieving other advantages taught or suggested herein. Further, some examples may achieve different advantages than those taught or suggested herein.

Some examples have been described in connection with the accompanying drawings. The figures may or may not be drawn and/or shown to scale, but such scale should not be limiting, since dimensions and proportions other than what are shown are contemplated and are within the scope of the disclosed invention. Distances, angles, etc. are merely illustrative and do not necessarily bear an exact relationship to actual dimensions and layout of the devices illustrated. Components may be added, removed, and/or rearranged. Further, the disclosure herein of any particular feature, aspect, method, property, characteristic, quality, attribute, element, or the like in connection with various examples may be used in all other examples set forth herein. Additionally, any methods described herein may be practiced using any device suitable for performing the recited steps.

For purposes of summarizing the disclosure, certain aspects, advantages and features of the inventions have been described herein. Not all, or any such advantages are necessarily achieved in accordance with any particular example of the inventions disclosed herein. No aspects of this disclosure are essential or indispensable. In many examples, the devices, systems, and methods may be configured differently than illustrated in the figures. or description herein. For example, various functionalities provided by the illustrated modules may be combined, rearranged, added, or deleted. In some implementations, additional or different processors or modules may perform some or all of the functionalities described with reference to the examples described and illustrated in the figures. Many implementation variations are possible. Any of the features, structures, steps, or processes disclosed in this specification may be included in any example.

What is claimed is:

1. An electronic assembly comprising:
an assembly substrate comprising one or more electrical connections; and
an electronic device mounted to a first surface of the assembly substrate, the electronic device comprising:
a plurality of electronic modules mounted on and electrically connected to a first surface of a device substrate, the device substrate having one or more traces; and
a busbar comprising:
a first portion extending along at least a portion of a lateral dimension of the device substrate; and
a second portion having one or more projections extending non-parallel and away from the first portion and between the plurality of electronic modules to electrically and mechanically connect to the one or more traces disposed on the first surface of the device substrate, the one or more projections comprising a thermally conductive material.

2. The electronic assembly of claim 1, further comprising a second electronic device mounted on and electrically connected to a second surface of the assembly substrate opposite from the first surface.

3. The electronic assembly of claim 1, wherein the first portion extends to at least partially cover the plurality of electronic modules.

4. The electronic assembly of claim 2, wherein the electronic device and the second electronic device are electrically connected are connected to each other by the one or more electrical connections.

5. The electronic assembly of claim 1, wherein the one or more projections are soldered to the one or more traces.

6. The electronic assembly of claim 1, wherein the first portion comprises a planar surface.

7. The electronic assembly of claim 1, wherein the busbar comprises a top surface, which top surface is substantially flat.

8. The electronic assembly of claim 7, wherein the top surface comprises a layer of insulation, the insulation electrically isolating the top surface.

9. The electronic assembly of claim 1, wherein the second portion comprises a lead frame.

10. The electronic assembly of claim 1, wherein the one or more projections comprise a projection insulating layer near the substrate.

11. The electronic assembly of claim 1, wherein the one or more projections can comprise at least one of a thin blade or a thick pillar.

12. The electronic assembly of claim 1, further comprising a metal clip soldered to the busbar, wherein the metal clip is connected to a power source and thereby provides power to the electronic assembly.

13. The electronic assembly of claim 1, wherein the first portion of the busbar comprises a heat sink portion configured to draw heat from (i) the device substrate and (ii) a top side of the plurality of electronic modules.

14. The electronic assembly of claim 1, wherein the plurality of electronic modules comprise a package and a passive component connected to the package, wherein the package comprises a molding compound.

15. An electronic package comprising:
a substrate comprising one or more traces disposed on a surface of the substrate and a voltage input and a voltage output connected to the one or more traces;
a plurality of electronic modules configured to be mounted on and electrically connected to the substrate, wherein the one or more traces are disposed between modules of the plurality of electronic module; and
a busbar extending along at least a portion of a length of the substrate, the busbar comprising one or more projections electrically and mechanically connected to the one or more traces.

16. The electronic package of claim 15, wherein the busbar comprises a top surface, which top surface is substantially flat.

17. The electronic package of claim 15, wherein the busbar comprises a lead frame.

18. The electronic package of claim 15, wherein the busbar comprises a heat sink portion configured to draw heat from the substrate and a top side of the plurality of electronic modules.

19. A method of manufacturing an electronic assembly, the method comprising:
providing a substrate comprising one or more traces and a voltage input and a voltage output connected to the one or more traces;
mounting an electronic device package comprising a plurality of electronic modules, so as to mechanically affix the electronic device package upon, and to electrically connect the electronic device package to, a first surface of the substrate, wherein the one or more traces are disposed between modules of the plurality of electronic modules;
mounting a second electronic device package, so as to mechanically affix the second electronic device package upon, and to electrically connect the second electronic device package to, a second surface of the substrate opposite from the first surface; and
mounting, to the substrate, a busbar extending along a length of the substrate, the busbar comprising one or more projections to electrically and mechanically connect to the one or more traces.

20. The method of claim 19, further comprising stamping the busbar to form the one or more projections and one or more tie bars on either side of one or more gaps from forming the one or more projections.
